(19) United States
(12) Patent Application Publication
(10) Pub. No.: US 2006/0228867 A1
(43) Pub. Date: Oct. 12, 2006

(54) Isolation region formation that controllably induces stress in active regions

(75) Inventors: Manoj Mehrotra, Plano, TX (US); Amitava Chatterjee, Plano, TX (US); Jin Zhao, Plano, TX (US)

Correspondence Address: TEXAS INSTRUMENTS INCORPORATED, P O BOX 655474, M/S 3999, DALLAS, TX, 75265, US

(73) Assignee: Taxas Instruments Incorporated

(21) Appl. No.: 11/104,038

(22) Filed: Apr. 12, 2005

(51) Int. Cl. H01L 21/76

(52) U.S. Cl. 438/435

(57) ABSTRACT

A method (10) of forming an isolation structure (140, 142) in a semiconductor substrate (102) is disclosed, wherein the isolation structure (140, 142) can be formed in a controlled manner so as to regulate stresses exerted by the structure on one or more active regions (106) of the substrate (102) located adjacent to the structure (140, 142).

### FIELD OF INVENTION

The present invention relates generally to semiconductor devices and more particularly to forming isolation regions in a semiconductor substrate in a manner that allows stresses to be controllably induced in active regions of the semiconductor substrate.

### BACKGROUND OF THE INVENTION

It can be appreciated that placing mechanical stresses (e.g., tension or compression) upon a semiconductor substrate can affect the performance of devices formed in and/or on the substrate. With regard to MOS transistors, for example, stressing the substrate can change charge mobility characteristics in respective channel regions of the transistors. This may be beneficial because, for a given electric field developed across the transistors, the amount of current that flows through the channel regions is directly proportional to the mobility of carriers in the channel regions. Thus, the higher the mobility of the carriers in the channel regions, the more rapidly the carriers will pass through the channel regions and the faster the transistors can perform. Improving the mobility of the carriers in the channel regions can also lower operating voltages, which may be desirable at times.

One drawback to improving channel mobility via strain is that compressive strain, which generally improves hole mobility for silicon substrate devices, can degrade electron mobility, and that tensile strain, which improves electron mobility for silicon substrate based devices, can degrade hole mobility. As a result, introducing tensile strain can improve performance of NMOS devices but degrade performance of PMOS devices. Similarly, introducing compressive strain can improve performance of PMOS devices but degrade performance of NMOS devices. Additionally, the impact of stress on NMOS and PMOS transistor mobility depends upon the channel orientation and surface orientation and is different for different orientations.

A mechanism that allows a degree of control to be exercised over stresses applied to a semiconductor substrate would thus be desirable.

### SUMMARY OF THE INVENTION

The following presents a simplified summary of the invention in order to provide a basic understanding of some aspects of the invention. This summary is not an extensive overview of the invention. It is intended neither to identify key or critical elements of the invention nor to delineate the scope of the invention. Rather, its primary purpose is merely to present one or more concepts of the invention in a simplified form as a prelude to the more detailed description that is presented later.

The present invention relates to forming one or more isolation regions within a semiconductor substrate in a manner that selectively strains one or more active regions in the substrate. The isolation regions, which may comprise shallow trench isolation (STI) regions, serve to electrically isolate the active regions from one another, where one or more semiconductor devices, such as MOS transistors, for example, can be formed within the active regions. The isolation regions are formed by applying two layers of dielectric material, where the first layer of dielectric material generally applies a tensile strain to the active regions, typically after a thermal anneal, and the second layer of dielectric material generally applies a compressive stress to the active regions.

According to one or more aspects of the present invention, a method of forming an isolation structure is disclosed. The method includes forming an isolation trench in a semiconductor substrate and then forming a first layer of dielectric material over the semiconductor substrate and down into the isolation trench. A second layer of dielectric material is then formed over the first layer of dielectric material. The substrate and the first and second layers of dielectric material are then subjected to an annealing process and excess amounts of the first and second layers of dielectric material are removed. The annealing process causes the first layer of dielectric material to contract and thereby exert a tensile stress on one or more active regions of the semiconductor substrate that surround the isolation structure.

According to one or more other aspects of the present invention, an isolation structure is disclosed. The isolation structure is formed within a semiconductor substrate adjacent to an active region of the semiconductor substrate. The isolation structure includes a first layer of dielectric material formed within an isolation trench formed within the semiconductor substrate adjacent to the active region. The structure also includes a second layer of dielectric material formed over the first layer of dielectric material, where the first layer of dielectric material exerts a tensile stress on the active region of the semiconductor substrate.

To the accomplishment of the foregoing and related ends, the following description and annexed drawings set forth in detail certain illustrative aspects and implementations of the invention. These are indicative of but a few of the various ways in which one or more aspects of the present invention may be employed. Other aspects, advantages and novel features of the invention will become apparent from the following detailed description of the invention when considered in conjunction with the annexed drawings.

### BRIEF DESCRIPTION OF THE DRAWINGS

FIG. 1 is a flow diagram illustrating an exemplary method for forming one or more isolation regions within a semiconductor substrate according to one or more aspects of the present invention.

FIGS. 2-6 are fragmentary cross sectional diagrams illustrating the formation of one or more exemplary isolation regions within a semiconductor substrate according to one or more aspects of the present invention, such as the methodology set forth in FIG. 1.

### DETAILED DESCRIPTION OF THE INVENTION

One or more aspects of the present invention are described with reference to the drawings, wherein like reference numerals are generally utilized to refer to like elements throughout, and wherein the various structures are not necessarily drawn to scale. It will be appreciated that where like acts, events, elements, layers, structures, etc. are reproduced, subsequent (redundant) discussions of the same may be omitted for the sake of brevity. In the following description, for purposes of explanation, numerous specific details are set forth in order to provide a thorough understanding of one or more aspects of the present invention. It may be evident, however, to one of ordinary skill in the art that one or more aspects of the present invention may be practiced with a lesser degree of these specific details. In other instances, known structures are shown in diagrammatic form in order to facilitate describing one or more aspects of the present invention.

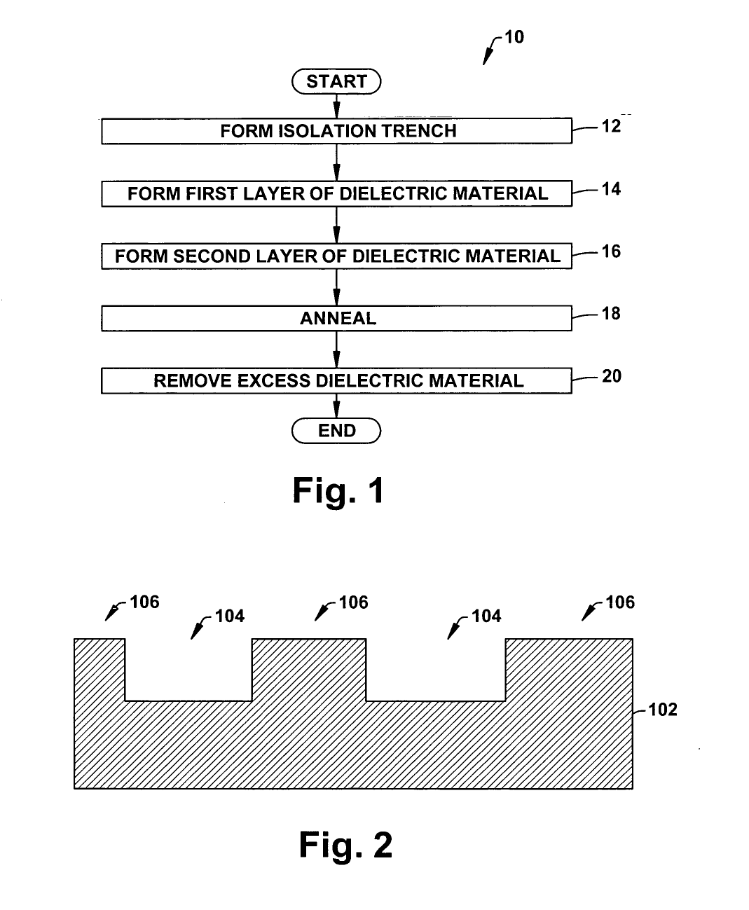

Turning to FIG. 1, an exemplary methodology 10 is illustrated for forming one or more isolation regions within a semiconductor substrate according to one or more aspects of the present invention, where the isolation regions may comprise shallow trench isolation (STI) regions. Although the methodology 10 is illustrated and described hereinafter as a series of acts or events, it will be appreciated that the present invention is not limited by the illustrated ordering of such acts or events. For example, some acts may occur in different orders and/or concurrently with other acts or events apart from those illustrated and/or described herein. In addition, not all illustrated steps may be required to implement a methodology in accordance with one or more aspects of the present invention. Further, one or more of the acts may be carried out in one or more separate acts or phases. It will be appreciated that a methodology carried out according to one or more aspects of the present invention may be implemented in association with the formation and/or processing of structures illustrated and described herein as well as in association with other structures not illustrated or described herein.

The methodology 10 begins at 12, wherein a semiconductor substrate 102 has one or more isolation trenches 104 formed therein (FIG. 2). It will be appreciated that the isolation trenches 104, and more particularly respective isolation regions subsequently formed therein, serve to electrically isolate active regions 106 of the substrate 102 from one another, where semiconductor devices, such as MOS transistors, for example, can be formed in the active regions 106. The semiconductor substrate 102 may comprise any type of semiconductor body, such as a semiconductor wafer or one or more die on a wafer, as well as any other type of semiconductor layers associated therewith. Further, the substrate 102 may comprise silicon and/or silicon germanium, for example.

The isolation trenches 104 can be formed in the substrate 102 in any suitable manner, such as with lithographic techniques, for example, where lithography broadly refers to processes for transferring one or more patterns between various media. In lithography, a light sensitive resist coating (not shown) is formed over one or more layers to which a pattern is to be transferred (e.g., the substrate 102). The resist coating is then patterned by exposing it to one or more types of radiation or light which (selectively) passes through an intervening lithography mask containing the pattern. The light causes the exposed or unexposed portions of the resist coating to become more or less soluble, depending on the type of resist used. A developer is then used to remove the more soluble areas leaving the patterned resist. The patterned resist can then serve as a mask for the underlying layer or layers which can be selectively treated (e.g., etched) to transfer the pattern thereto.

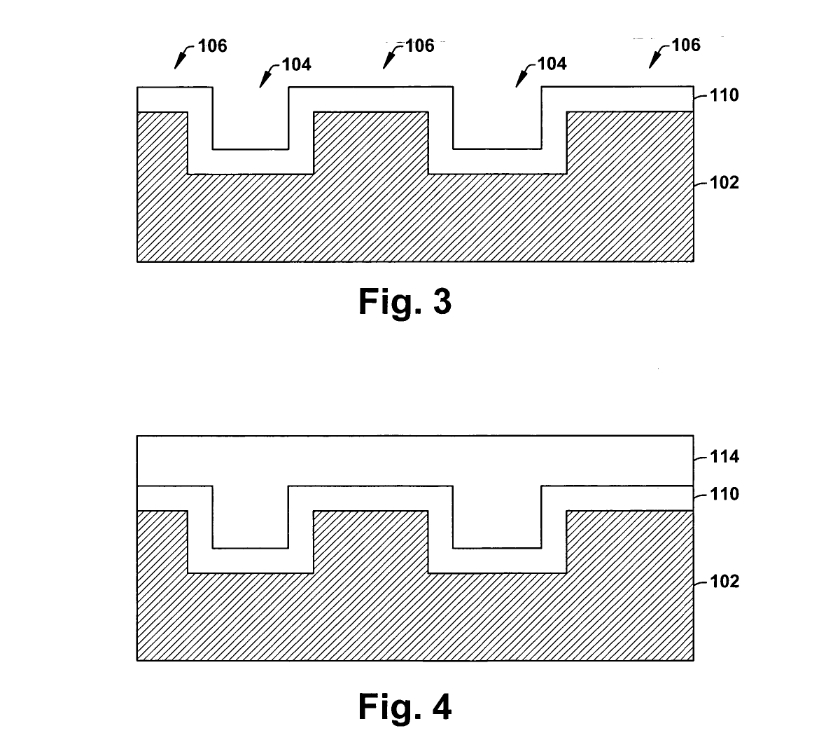

A first layer of dielectric material 110 is then formed over the active areas 106 and down into the trenches 104 at 14 (FIG. 3). The first layer of dielectric material 110 is preferable formed via a chemical vapor deposition (CVD) process and may comprise an oxide based material and/or TEOS (Tetraethyl Orthosilicate), for example. Further, the first layer of dielectric material 110 may be formed to a thickness of between about 50 to about 150 Angstroms. It will be appreciated that a thin layer of liner oxide (not shown) on the order of about 50 Angstroms can be formed before the first layer of dielectric material 110 is formed, or this layer can be omitted (as in the illustrated example) with the first layer of dielectric material 110 substituting for this layer. Additionally, a layer of protective material (not shown), such as a layer of nitride based material, for example, may be formed over the active regions to protect those regions from subsequent processing. Such a layer of protective material may, for example, inhibit the first layer of dielectric material 110 from coming into contact with the active regions 106. Similarly, such a protective layer may serve as a chemical mechanical polishing (CMP) stopping layer, for example.

At 16, a second layer of dielectric material 114 is formed over the first layer of dielectric material 110 (FIG. 4). The second layer of dielectric material 114 is preferably formed via a high density plasma (HDP) process and may include an oxide based material, for example. The second layer of dielectric material 114 may be formed to a thickness of between about 4000 to about 7000 Angstroms, for example.

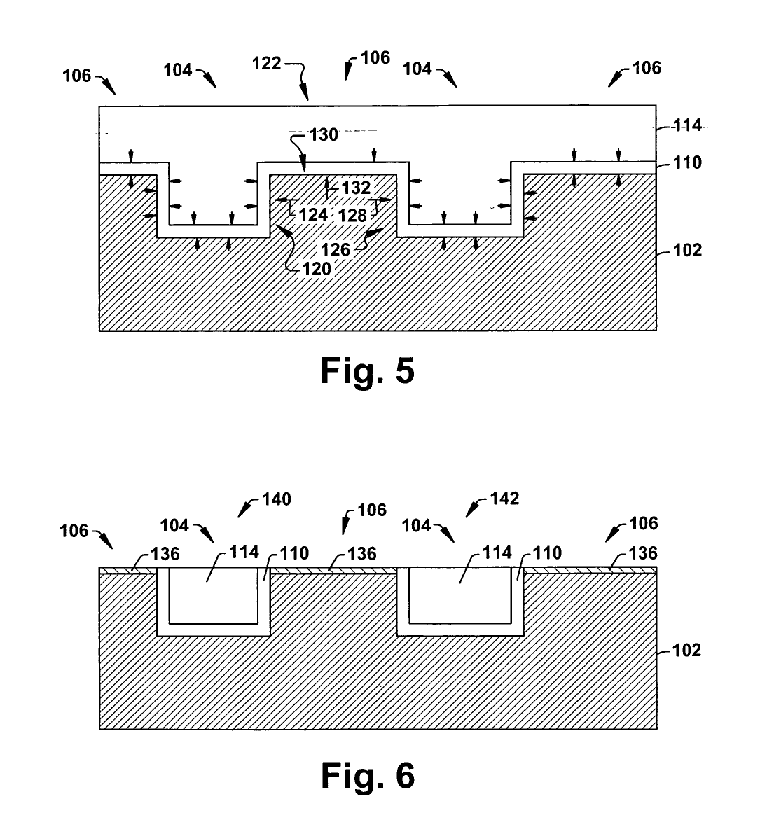

The substrate 102 and first 110 and second 114 layers of dielectric material are then subjected to a thermal annealing process at 18 (FIG. 5). According to one or more aspects of the present invention, exposing the first layer of dielectric material 110 to heat causes it to shrink (as illustrated by small arrows), such as by densification, for example. In one example, the annealing process comprises heating to a temperature of between about 900 degrees Celsius and about 1100 degrees Celsius for a time of between about 30 minutes and about 60 minutes.

It can be appreciated that shrinking the first layer of dielectric material 110 causes a tensile strain to be imposed upon the active regions 106 within the substrate 102 since active regions 106 are mechanically bonded to or adhered to the first layer of dielectric material 110. For example, the left side 120 of the middle active region 122 is “pulled on” in the direction indicated by arrow 124, and the right side 126 of the middle active region 122 is “pulled on” in the direction indicated by arrow 128 as the first layer of dielectric material 110 is heated. Similarly, the top 130 of the middle active region 122 may be “pulled on” in the direction indicated by arrow 132 as the first layer of dielectric material 110 shrinks.

Excess dielectric material, from the first 110 and/or second 114 layers of dielectric material is then removed at 20, such as via a chemical mechanical polishing (CMP) process, for example, (FIG. 6). In this manner, respective isolation regions 140 and 142 are established within the isolation trenches 104. The isolation regions 140 and 142 are substantially flush with the now exposed surrounding portions of the semiconductor substrate 102, and serve to separate and electrically isolate the active regions 106 from one another (and thus also semiconductor devices, such as transistors, formed within the active regions 106). It will be appreciated that while two trenches 104, and thus two isolation regions 140, 142, and three active regions 106 are depicted in the illustrated example, that any suitable number of such regions can be formed according to one or more aspects of the present invention. In the illustrated example, the active regions 106 are covered with a thin layer of a protective material 136, such as a nitride based material, for example. This layer of material 136 protects the active regions 106 wherein the semiconductor devices are to be formed. In the illustrated example, this protective layer 136 may have served as a CMP stopping layer so that the active regions weren't impinged upon or damaged by the CMP processing carried out at 20. The protective layer 136 can be removed prior to device formation in the active regions 106, such as by an acid washing, for example.

It can be appreciated that semiconductor devices (not shown) can then be formed within the different active regions 106. Generally speaking, to establish transistors in any of the active regions, a gate structure and source and drain regions are formed in the active regions, after which silicide, metallization, and/or other back-end processing can be performed. To form the gate structure, a thin layer of gate oxide material is formed over the upper surface of the active regions. The gate oxide layer can be formed by any suitable material formation process, such as thermal oxidation processing, for example. By way of example, the oxide layer can, for example, be formed to a thickness of between about 20 Angstroms and about 500 Angstroms at a temperature of between about 800 degrees Celsius and about 1000 degrees Celsius in the presence of O₂. This layer of oxide material can serve as a gate oxide in a high voltage CMOS transistor device, for example. Alternatively, a layer of oxide material having a thickness of about 70 Angstroms or less can be formed to serve as a gate oxide in a low voltage CMOS transistor device, for example.

A layer of gate electrode material (e.g., of polysilicon or other conductive material) is then deposited over the layer of gate oxide material. The polysilicon layer can, for example, for formed to between about 1000 to about 5000 Angstroms, and may include a dopant, such as a p-type dopant (Boron) or n-type dopant (e.g., Phosphorus), depending upon the type(s) of transistors to be formed. The dopant can be in the polysilicon as originally applied, or may be subsequently added thereto (e.g., via a doping process). The gate oxide and gate electrode layers are then patterned to form the gate structure, which comprises a gate dielectric and a gate electrode, and which is situated over a channel region in the silicon active regions.

With the patterned gate structure formed, LDD, MDD, or other extension implants can be performed, for example, depending upon the type(s) of transistors to be formed, and left and right sidewall spacers can be formed along left and right lateral sidewalls of the patterned gate structure. Implants to form the source region and drain regions are then performed, wherein any suitable masks and implantation processes may be used in forming the source and drain regions to achieve the desired transistor types. For example, a PMOS source/drain mask may be utilized to define one or more openings through which a p-type source/drain implant (e.g., Boron (B and/or BF₂)) is performed to form p-type source and drain regions for PMOS transistor devices. Similarly, an NMOS source/drain mask may be employed to define one or more openings through which an n-type source/drain implant (e.g., Phosphorous (P) and/or Arsenic (As)) is performed to form n-type source and drain regions for NMOS transistor devices. Depending upon the types of masking techniques employed, such implants may also selectively dope the poly-silicon of the gate structure of certain transistors, as desired. It will be appreciated that the channel region is thus defined between the source and drain regions in the different transistors. It will also be appreciated that the channel region can be doped prior to forming the gate oxide to adjust Vt's as desired.

It will be appreciated that the recipe employed in forming isolation regions according to one or more aspects of the present invention can be altered to achieve desired stresses in the active regions (e.g., by selectively controlling the amount that the first layer of dielectric material 110 contracts). For example, the amount and/or type of material utilized for the first layer of dielectric material 110 and/or the annealing time and/or temperature can be altered to tension the active regions 106 by a desired amount. Similarly, the amount and/or type of material and/or the process used for forming the second layer of dielectric material 114 can be altered to desirably affect the stress in the active regions 106.

The ordering of the acts or events of the methodology 10 can also be altered. For example, the annealing process can be performed right after the first layer of dielectric material 110 is formed but before the second layer of dielectric material 114 is formed. Likewise, excess dielectric material can be removed before the annealing process.

It will also be appreciated, however, that the second layer of dielectric material 114 generally applies a compressive strain to the active regions 106 (e.g., via “pushing” on the first layer of dielectric material 110), and that since there is generally a substantially greater amount of the second layer of dielectric material 114 than the first layer of dielectric material 110 (e.g., the second layer of dielectric material 114 is substantially thicker than the first layer of dielectric material 110), the active regions 106 may experience a net compressive strain. In such situation, the recipe for forming the isolation regions, which may constitute shallow trench isolation (STI) regions, may be selectively controlled to mitigate the degree to which the active regions 106 are compressed.

Further, forming an isolation region as described herein is simple and efficient as it can be performed as part of a semiconductor fabrication process. Stressing an active region in a manner set forth herein allows active width related effects to be improved to enhance SRAM, logic beta ratios and/or threshold voltage (Vt) vs. width (W) characteristics, which can in turn improve process and functional yield, where logic beta ratios provide an indication of SRAM stability and correspond to ratios of NMOS drive current to PMOS drive current. Additionally, providing tensile stress or mitigating compressive stress can enhance electron mobility for NMOS devices which can in turn improve drive current, particularly for narrow width NMOS transistors.

It will be appreciated that while reference is made throughout this document to exemplary structures in discussing aspects of methodologies described herein (e.g., those structures presented in FIGS. 2-6 while discussing the methodology set forth in FIG. 1), that those methodologies are not to be limited by the corresponding structures presented. Rather, the methodologies (and structures) are to be considered independent of one another and able to stand alone and be practiced without regard to any of the particular aspects depicted in the Figs.

It is also to be appreciated that layers and/or elements depicted herein are illustrated with particular dimensions relative to one another (e.g., layer to layer dimensions and/or orientations) for purposes of simplicity and ease of understanding, and that actual dimensions of the elements may differ substantially from that illustrated herein. For example, the second layer of dielectric material 114 is generally substantially thicker than the first layer of dielectric material 110.

Additionally, unless stated otherwise and/or specified to the contrary, any one or more of the layers set forth herein can be formed in any number of suitable ways, such as with spin-on techniques, sputtering techniques (e.g., magnetron and/or ion beam sputtering), (thermal) growth techniques and/or deposition techniques such as atomic layer deposition (ALD), chemical vapor deposition (CVD), physical vapor deposition (PVD), atmospheric pressure CVD (APCVD), low pressure CVD (LPCVD), metal-organic CVD (MOCVD) and/or plasma enhanced CVD (PECVD), for example, and can be patterned in any suitable manner (unless specifically indicated otherwise), such as via etching and/or lithographic techniques, for example. Further, the term “exemplary” as used herein merely meant to mean an example, rather than the best.

Although one or more aspects of the invention has been shown and described with respect to one or more implementations, equivalent alterations and modifications will occur to others skilled in the art based upon a reading and understanding of this specification and the annexed drawings. The invention includes all such modifications and alterations and is limited only by the scope of the following claims. In addition, while a particular feature or aspect of the invention may have been disclosed with respect to only one of several implementations, such feature or aspect may be combined with one or more other features or aspects of the other implementations as may be desired and/or advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

What is claimed is:

1. A method of forming an isolation structure, comprising:
forming an isolation trench in a semiconductor substrate;
forming a first layer of dielectric material over the semiconductor substrate and down into the isolation trench;
forming a second layer of dielectric material over the first layer of dielectric material;
annealing the substrate and the first and second layers of dielectric material; and
removing excess amounts of the first and second layers of dielectric material, where the annealing process causes the first layer of dielectric material to contract and thereby exert a tensile stress on one or more active regions of the semiconductor substrate that surround the isolation structure.

2. The method of claim 1, wherein the first layer of dielectric material is formed via a chemical vapor deposition (CVD) process.

3. The method of claim 2, wherein the second layer of dielectric material is formed via a high density plasma (HDP) process.

4. The method of claim 3, wherein the first layer of dielectric material comprises at least one of an oxide based material and TEOS (Tetraethyl Orthosilicate).

5. The method of claim 4, wherein the second layer of dielectric material comprises an oxide based material.

6. The method of claim 5, wherein the first layer of dielectric material is formed to a thickness of between about 50 to about 150 Angstroms.

7. The method of claim 6, wherein the second layer of dielectric material is formed to a thickness of between about 4000 to about 7000 Angstroms.

8. The method of claim 7, wherein the annealing process comprises at least one of heating to a temperature of between about 900 degrees Celsius and about 1100 degrees Celsius, and heating for a duration of between about 30 minutes and about 60 minutes.

9. The method of claim 8, wherein the second layer of dielectric material exerts a compressive stress on the active regions.

10. The method of claim 9, wherein the excess dielectric material is removed via a chemical mechanical polishing (CMP) process.

11. The method of claim 10, wherein the annealing process is performed after the first layer of dielectric material is formed, but prior to forming the second layer of dielectric material to reduce the tensile stress exerted on the active regions.

12. The method of claim 10, wherein a net compressive stress is exerted on the active regions and the tensile stress exerted by the first dielectric layer merely mitigates the compressive stress.

13. The method of claim 10, wherein excess dielectric material is removed prior to the annealing process.

14. The method of claim 10, wherein the tensile stress exerted on the active regions enhances electron mobility.

15. An isolation structure formed within a semiconductor substrate adjacent to an active region of the semiconductor substrate, the isolation structure comprising:
a first layer of dielectric material formed within an isolation trench formed within the semiconductor substrate adjacent to the active region; and
a second layer of dielectric material formed over the first layer of dielectric material, where the first layer of dielectric material exerts a tensile stress on the active region.

16. The structure of claim 15, where the first layer of dielectric material exerts the tensile stress as a result of an annealing process.

17. The structure of claim 16, wherein at least one of the first layer of dielectric material is formed via a chemical vapor deposition (CVD) process and the second layer of dielectric material is formed via a high density plasma (HDP) process.

18. The structure of claim 17, wherein at least one of the first layer of dielectric material comprises at least one of an oxide based material and TEOS (Tetraethyl Orthosilicate) and the second layer of dielectric material comprises an oxide based material.

19. The structure of claim 18, wherein at least one of the first layer of dielectric material is formed to a thickness of between about 50 to about 150 Angstroms, the second layer of dielectric material is formed to a thickness of between about 4000 to about 7000 Angstroms and the annealing process comprises at least one of heating to a temperature of between about 900 degrees Celsius and about 1100 degrees Celsius, and heating for a duration of between about 30 minutes and about 60 minutes.

20. The structure of claim 19, wherein the second layer of dielectric material exerts a compressive stress on the active region.
